(19) United States
(12) Patent Application Publication
(10) Pub. No.: US 2024/0274507 A1
(43) Pub. Date: Aug. 15, 2024

(54) Vias for Semiconductor Devices Formed from Multiple Etching

(71) Applicant: Wolfspeed, Inc., Durham, NC (US)

(72) Inventors: Kyle Bothe, Cary, NC (US); Chris Hardiman, Cary, NC (US); Scott Sheppard, Chapel Hill, NC (US)

(21) Appl. No.: 18/168,985

(22) Filed: Feb. 14, 2023

(51) Int. Cl. H01L 23/48; H01L 21/768; H01L 23/528; H01L 29/20; H01L 29/205; H01L 29/778

(52) U.S. Cl. CPC H01L 23/481; H01L 21/76898; H01L 23/5283; H01L 29/2003; H01L 29/205; H01L 29/7786

(57) ABSTRACT

Semiconductor devices are provided. In one example, a semiconductor device includes a substrate. The semiconductor device includes a nitrogen-polar (N-polar) Group III-nitride semiconductor structure on the substrate. The semiconductor device includes a via passing through the substrate and the N-polar Group III-nitride semiconductor structure. A cross-sectional profile of the via changes at an interface between the substrate and the N-polar Group III-nitride semiconductor structure.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a substrate. The semiconductor device includes a nitrogen-polar (N-polar) Group III-nitride semiconductor structure on the substrate. The semiconductor device includes a via passing through the substrate and the N-polar Group III-nitride semiconductor structure. A cross-sectional profile of the via changes at an interface between the substrate and the N-polar Group III-nitride semiconductor structure.

One example aspect of the present disclosure is directed to a transistor device. The transistor device includes a substrate having a first side and an opposing second side. The transistor device includes a nitrogen-polar (N-polar) Group III-nitride semiconductor structure having a first side and an opposing second side. The first side of the N-polar Group III-nitride semiconductor structure is on the second side of the substrate to define an interface. The transistor device includes a via passing through the substrate and the N-polar Group III-nitride semiconductor structure. The via has a first cross-sectional width at the second side of the N-polar Group III-nitride semiconductor structure and a second cross-sectional width at the interface. The first cross-sectional width is greater than or equal to the second cross-sectional width.

One example aspect of the present disclosure is directed to a method for forming a semiconductor device. The semiconductor device includes a nitrogen-polar (N-polar) Group III-nitride semiconductor structure on a substrate. The method includes performing a first etch on an outer surface of the N-polar Group III-nitride semiconductor structure. The method includes performing a second etch on an outer surface of the substrate. The first etch and the second etch combine to produce a via passing through the substrate and the N-polar Group III-nitride semiconductor structure.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a cross-sectional view of an example semiconductor device having a semiconductor structure according to example embodiments of the present disclosure.

FIGS. 2A-2F depict cross-sectional views of example fabrication of a via in an example semiconductor device according to example embodiments of the present disclosure.

FIG. 3 depicts a cross-sectional view of an example via in an example semiconductor device according to example embodiments of the present disclosure.

FIG. 4 depicts a cross-sectional view of an example via in an example semiconductor device according to example embodiments of the present disclosure.

FIG. 5 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistors (HEMTs), may be used in power electronics applications. HEMTs fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity. As such, Group III-Nitride based HEMTs may be promising candidates for high frequency and/or high-power RF applications (as well as for low frequency high power switching applications) as discrete transistors or as coupled with other circuit elements, such as in monolithic microwave integrated circuit (MMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

HEMT devices may include nitrogen-polar (e.g., N-polar) Group III-nitride semiconductor structures. These N-polar Group III-nitride semiconductor structures have recently been shown to deliver significant performance advantages, particularly at operating frequencies in the mm wave frequency ranges (e.g., 30 GHz or greater) relative to traditional metal polar Group-III nitride structures. For fabrication, the N-polar group III-nitride semiconductor structure can be epitaxially grown on top of a substrate, such as a silicon carbide substrate, with the N-polar growth direction extending away from the substrate.

Generally, the source and drain of a HEMT device can be electrically coupled to other components, such as components of a semiconductor package. In some instances, the electrical connection to the source contact may occur using a through-wafer via. That is, a conductive portion (e.g., conductive element or other form of conductive pathway) connects to the source contact on the frontside of the HEMT device, then extends through both the semiconductor structure and substrate, and ultimately provides a subsequent electrical connection point on the backside of the HEMT device, or on the side of the substrate that is opposite the source contact.

In some instances, through-wafer vias can be formed using etching (e.g., wet etching) during backside processing of the HEMT device. In these processes, the backside of the HEMT device, (e.g., the backside of the substrate), is partially masked to define an exposed surface area. A liquid etch material can then be brought into contact with the exposed surface area of the substrate to begin etching material away from the HEMT device. The wet etch will initially remove material from the substrate and then subsequently remove material from the adjacent semiconductor structure device as the wet etch continues inwards.

However, N-polar group III-nitride semiconductor structures are shown to be chemically resistive to backside wet etching. Namely, as a result of the N-polar direction extending the same direction as the backside wet etch direction, the interface between the N-polar Group III-nitride structure and the substrate is not conducive for wet etching that initiates from the substrate side of the semiconductor device.

Example aspects of the present disclosure provide for multiple etching of a semiconductor device (e.g., HEMT device), such as using both frontside and backside processing. The semiconductor structure can be an N-polar group III-nitride semiconductor structure having an N-polar direction extending away from substrate towards the frontside of the HEMT device. The frontside of the HEMT device can be etched, such as using one or more wet etching or dry etching processes. The substrate, such as a silicon carbide substrate, can be etched using a separate etching process, such as using one or more wet etching processes. The multiple etching processes will meet at one or more interfaces, such as at the interface between the N-polar group III-nitride semiconductor structure and the substrate, to provide a via extending through the semiconductor device. Thus, the resulting via can facilitate a connection of conductive material in the via extending from an electrode (e.g., a source contact) to the backside of the semiconductor device.

In some embodiments, the semiconductor structure of the semiconductor device may include a nitrogen-polar (N-polar) Group III-nitride semiconductor structure on the substrate. The N-polar Group II-nitride semiconductor structure can have an N-face at a surface opposite the substrate. The substrate may be a silicon carbide substrate. The via can extend through the substrate and the N-polar Group III-nitride semiconductor structure, and can have a cross-sectional profile that changes, such as at the interface between the substrate and the N-polar Group III-nitride semiconductor structure. The via may have a first cross-sectional profile in the N-polar Group III-nitride semiconductor structure that is substantially constant, or that narrows as it approaches the interface. Thus, the via may have a first cross-sectional width at the frontside of the semiconductor device that is larger than or equal to a second cross-sectional width of the via at the interface. The via may have a second cross-sectional profile in the substrate that narrows as it approaches the interface. Thus, the via may have a third cross-sectional width at the backside of the semiconductor device that is larger than its second cross-sectional width at the interface. The via may have an hourglass-shaped cross-sectional profile, such as having a narrow convergence the hourglass-shaped cross-sectional profile at the interface. The via may have additional cross-sectional profiles, such as three or more cross-sectional profiles, as a result of a plurality of etching processes, such s three or more etching processes.

Examples of the present disclosure provide technical effects and benefits. For instance, semiconductor devices (e.g., HEMT devices) with N-polar group III-nitride semiconductor structures are provided with vias passing through both the N-polar group III-nitride semiconductor structure and the substrate. The via may be formed using duel frontside and backside etching process in the semiconductor structure and substrate, respectively. The resulting via facilitates interconnection of the device using through-wafer connections. For instance, forming vias in this way facilitates the use of N-polar Group III-nitride semiconductor structures in semiconductor devices, such as HEMTs, for a wide variety of applications, including high frequency, and/or high-power RF applications (e.g., greater than about 30 GHz). Examples of the present disclosure may thus provide access to high power and/or high frequency RF performance associated with N-polar Group III-nitride semiconductor structures, while still enabling through-wafer connections.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure, such as Schottky rectifiers.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

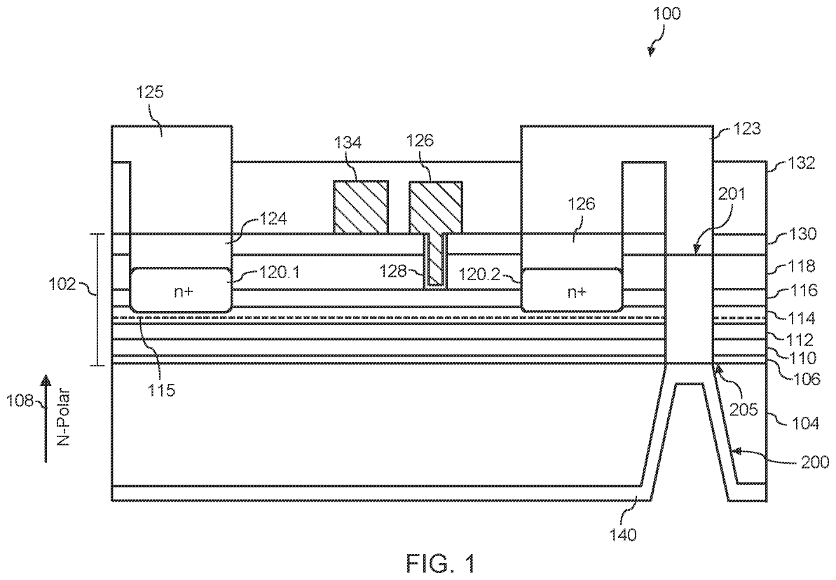

FIG. 1 depicts a cross-sectional view of an example semiconductor device 100, according to example embodiments of the present disclosure. FIG. 1 is intended to represent structures for identification and description and is not intended to represent the structures to physical scale. The example semiconductor device 100 is exemplary illustrated as, and also referred to herein, as a HEMT device 100, though other types of semiconductor devices may also be realized without deviating from the scope of the present disclosure.

The HEMT device 100 may include a semiconductor structure 102 on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100. In some examples, the substrate 104 of the HEMT device 100 may be a thinned substrate 104. In some examples, the substrate 104 may have a thickness in a range of, for instance, about 50 μm to about 300 μm, such as in range of about 75 μm to about 200 μm, such as about 100 μm. The HEMT device 100 may further include a metal layer 140 on the backside of the substrate 104, i.e., the side of the substrate 104 opposite the semiconductor structure 102. The metal layer 140 can comprise, for example, one or more conductive materials suitable for facilitating one or more ohmic connections with the HEMT device 100.

The semiconductor structure 102 on the substrate 104 may be a Group III-nitride semiconductor structure, such as an N-polar Group III-nitride semiconductor structure. As used herein, the term “Group III-nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements. As used herein, the term “N-polar Group III-nitride” refers to a Group III-nitride semiconductor structure having an outward facing nitrogen face “N-face” in the growth direction 108 (e.g., epitaxial growth direction) of the semiconductor structure 102.

The semiconductor structure 102 may be formed by epitaxial growth on the substrate 104 using, for instance, metal-organic chemical vapor deposition (MOCVD), molecular beam epitaxy (MBE), or hydride vapor phase epitaxy (HYPE). Techniques for epitaxial growth of Group III-nitrides have been described in, for example, U.S. Pat. Nos. 5,210,051, 5,393,993, and 5,523,589, the disclosures of which are incorporated by reference herein.

The semiconductor structure 102 of the HEMT device 100 may include a variety of different structures, such as a variety of different N-polar Group III-nitride semiconductor structures, without deviating from the scope of the present disclosure. For instance, in the example HEMT device 100 of FIG. 1, the semiconductor structure 102 includes a first layer 106 located on the substrate 104. The first layer 106 may be a nucleation layer for the semiconductor structure 102. The nucleation layer may be, for instance, a gallium nitride (GaN) layer and/or an aluminum nitride (AlN) layer to provide a crystal structure transition between, for instance, the substrate 104, and the semiconductor structure 102. In some examples, the first layer 106 may be an N-polar Group III-nitride, such as AlᵤGa₁₋ᵤN, where 0.5≤u≤1. In some examples, the aluminum mole fraction u is approximately 1, indicating that the first layer 106 is AlN. The first layer 106 may or may not include other Group III-nitrides such as InGaN, AlInGaN or the like. The first layer 106 may be undoped. The first layer 106 may be deposited on the substrate 104 using, for instance, metal-organic chemical vapor deposition (MOCVD), molecular beam epitaxy (MBE), or hydride vapor phase epitaxy (HVPE).

The semiconductor structure 102 may include several other layers. For instance, in the example HEMT device 100 of FIG. 1, the semiconductor structure 102 includes a second layer 110 (e.g., buffer layer), a barrier layer 112, a channel layer 114, first cap layer 116, and a second cap layer 118 (e.g., thick cap layer). However, those of ordinary skill in the art, using the disclosures provided herein, will understand that aspects of the present disclosure are applicable to devices having semiconductor structures with different layer arrangements.

The second layer 110 (e.g., buffer layer) may be an N-polar Group III nitride, such as AlᵥGa₁₋ᵥN, where 0≤v<0.1. In some embodiments, the aluminum mole fraction v is approximately 0 (e.g., 0.05 or less), indicating that the second layer 110 is GaN. The second layer 110 may or may not include other Group III-nitrides such as InGaN, AlInGaN or the like. The second layer 110 may be undoped and may be grown to a thickness in the range of about 0.5 μm to about 5 μm, such as about 2 μm. The second layer 110 may be a multi-layer structure, such as a superlattice or combinations of GaN, AlGaN or the like. The second layer 110 may be under compressive strain in some embodiments.

The semiconductor structure 102 may include the barrier layer 112 on the buffer layer 110. The barrier layer 112 may be an N-polar Group III nitride, such as Al_{w}Ga_{1-w}N where 0.1≤w<0.4, indicating that the barrier layer 112 is an AlGaN layer. In some embodiments, the barrier layer 112 may be a ScAlN layer or a ScAlGaN layer. The barrier layer 112 may or may not include other Group III-nitrides such as InGaN, AlInGaN or the like. The barrier layer 112 may act as a back barrier layer or barrier layer for the HEMT device 100. The barrier layer 112 may have a different band gap relative to the channel layer 114. The barrier layer 112 may have a thickness in a range of about 250 Angstroms to about 350 Angstroms, such as about 300 Angstroms.

In some embodiments, the barrier layer 112 may be a multilayer structure. For instance, in one example, the barrier layer 112 may include a first layer of n+doped GaN with a thickness of about 100 Angstroms. The barrier layer 112 may include a second layer of graded Al_{w.1}Ga_{1-w.1}N on the first layer, where w.1 varies from about 0.05 to about 0.4. The second layer of graded Al_{w}Ga_{1-w}N may have a thickness of about 100 Angstroms. The barrier layer 112 may include a third layer of Al_{w.2}Ga_{1-w.2}N on the second layer, where w.2 is in a range of 0.3 to 0.4. The thickness of the third layer is about 100 Angstroms. The barrier layer 112 may include a fourth layer of AlN on the third layer. The thickness of the fourth layer may be in a range of about 5 Angstroms to about 15 Angstroms, such as about 7 Angstroms.

The semiconductor structure 102 may include the channel layer 114 on the barrier layer 112. The channel layer 114 may be an N-polar Group III-nitride, such as AlₓGa₁₋ₓN, where 0≤x<0.1, provided that the energy of the conduction band edge of the channel layer 114 is less than the energy of the conduction band edge of the barrier layer 112 at the interface between the channel layer 114 and the barrier layer 112. The channel layer 114 may have a band gap that is different than the band gap of the barrier layer 112. In some embodiments, the aluminum mole fraction x is approximately 0 (e.g., 0.05 or less), indicating that the channel layer 114 is GaN. The channel layer 114 may or may not include other Group III-nitrides such as InGaN, AlInGaN or the like. The channel layer 114 may have a thickness in a range of about 75 Angstroms to about 125 Angstroms, such as about 100 Angstroms.

A 2DEG 115 may be induced in the channel layer 114 at the interface between the channel layer 114 and the barrier layer 112. The 2DEG 115 is highly conductive and allows conduction between the source and drain regions of the HEMT device 100. The 2DEG 115 may be controlled under operation of a gate, such that the HEMT device 100 acts as a controllable transistor device.

The semiconductor structure 102 may further include the first cap layer 116 (e.g., an AlGaN cap layer) on the channel layer 114. The first cap layer 116 may be an N-polar Group III-nitride, such as Al_{y}Ga_{1-y}N where 0.1≤y<0.4, indicating that the first cap layer 116 is an AlGaN layer. In some embodiments, the aluminum mole fraction y is in a range of about 0.2 to about 0.3. In some embodiments, the first cap layer 116 may be a ScAlN layer or a ScAlGaN layer. The first cap layer 116 may or may not include other Group III-nitrides such as InGaN, AlInGaN or the like. The first cap layer 116 may have a band gap that is different than the band gap of the channel layer 114. The first cap layer 116 may have a thickness in a range of about 15 Angstroms to about 50 Angstroms, such as about 26 Angstroms.

The semiconductor structure 102 may further include the second cap layer 118 (e.g., thick cap layer) on the first cap layer 116. The second cap layer 118 may be an N-polar Group III-nitride, such as Al_{z}Ga_{1-z}N, where 0≤z<0.1. In some embodiments, the aluminum mole fraction x is approximately 0 (e.g., 0.05 or less), indicating that the channel layer 114 is a GaN layer. The second cap layer 118 may or may not include other Group III-nitrides such as InGaN, AlInGaN or the like. The second cap layer 118 buries the channel layer 114 below the surface of semiconductor structure 102 such that the channel layer 114 is a buried layer at a depth of about, for example, 275 Angstroms or greater from the surface of the semiconductor structure 102, such as about 500 Angstroms or greater from the surface of the semiconductor structure 102, such as in a range of about 275 Angstroms to about 1000 Angstroms from the surface of the semiconductor structure 102. The second cap layer 118 may have a thickness in a range of about 250 Angstroms to about 1000 Angstroms, such as about 500 Angstroms.

The semiconductor structure 102 includes implanted regions 120.1 and 120.2. The implanted regions 120.1 and 120.2 include a distribution of implanted dopants (e.g., ions) of a first conductivity type such that the implanted regions 120.1 and 120.2 are n-type regions. The implanted regions 120.1 and 120.2 extend through the semiconductor structure 102 and into the channel layer 114.

The implanted regions 120.1 and 120.2 may include a distribution of implanted dopants extending into the channel layer 114. The implanted dopants may be of a first conductivity type such that the implanted regions 120.1 and 120.2 are each an n-type region as illustrated. The implanted dopants may be, for instance, silicon, germanium, sulfur, and/or oxygen ions.

The implanted regions 120.1 and 120.2 may each have a distribution of implanted dopants that extends to a depth from the surface of the semiconductor structure 102. The depth may be about 275 Angstroms or greater, such as about 500 Angstroms or greater, such as in a range of about 275 Angstroms to about 1000 Angstroms. The distribution of implanted dopants may extend through the second cap layer 118, the first cap layer 116 and to the channel layer 114. In some embodiments, the distribution of implanted dopants may extend into the barrier layer 112 and/or into the buffer layer 110 of the semiconductor structure 102.

The implanted regions 120.1 and 120.2 may each have a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted regions 120.1 and 120.2. The distribution of implanted dopants in the implanted regions 120.1 and 120.2 may have its peak dopant concentration at a depth in the implanted regions 120.1 and 120.2 close to channel layer 114 of the semiconductor structure 102. For instance, the peak dopant concentration may be in a region within the implanted regions 120.1 and 120.2. The region may be within 50 Angstroms or less of the channel layer 114. In some examples, the region may be within the buried channel layer 114. In some examples, the distribution of implanted dopants may provide a substantially uniform concentration of implanted dopants throughout the implanted regions 120.1 and 120.2 of the semiconductor structure 102.

As illustrated in FIG. 1, the HEMT device 100 may include electrodes on the implanted regions 120.1 and 120.2. More particularly, the HEMT device 100 may include a source contact 122 on the implanted region 120.2. The HEMT device 100 may include a drain contact 124 on the implanted region 120.1. The electrodes may form an ohmic contact with the respective implanted regions 120.1 and 120.2. The implanted dopants within implanted region 120.2 may provide a low resistive path between the ohmic source contact 122 and the channel layer 114. For instance, the implanted region 120.2 may have a dopant concentration such that the implanted region 120.2 has a resistivity in a range of about 0.2 Ohms-mm or less. The implanted dopants within implanted region 120.1 may provide a low resistive path between the ohmic drain contact 124 and the channel layer 114. For instance, the implanted region 120.1 may have a dopant concentration such that the implanted region 120.1 has a resistivity in a range of about 0.2 Ohms-mm or less.

The source contact 122 and the drain contact 124 may be laterally spaced apart from each other. In some embodiments, the source contact 122 and the drain contact 124 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSix, titanium silicide (TiSi), titanium nitride (TiN), tungsten silicon nitride (WSiN), platinum (Pt) and the like. In some embodiments, the source contact 122 may be an ohmic contact. The drain contact 124 may be an ohmic contact. In some embodiments, the source contact 122 and/or the drain contact 124 may include a plurality of layers to form an ohmic contact that may be provided as described, for example, in U.S. Pat. Nos. 8,563,372 and 9,214,352, the disclosures of which are incorporated by reference herein.

The HEMT device 100 may further include a gate contact 126. The gate contact 126 may extend at least partially through a trench (e.g., an ALE defined trench) in the second cap layer 118 so that the gate contact 126 is proximate to the first cap layer 116. In some examples, the gate contact 126 may have a gate length in a range of about 50 nm to about 150 nm. The gate length is the length of the gate contact 126 along the surface proximate the first cap layer 116.

A passivation layer 128 may be located between the gate contact 126 and the first cap layer 116. The passivation layer 128 may be SiN. Other suitable dielectric layers may be used as the passivation layer 128, such as SiO₂, MgOx, MgNx, ZnO, SiNx, SiOx or other dielectric layers. The passivation layer 128 may be formed, for instance, using MOCVD process(s), atomic layer deposition (ALD) process(s), and/or sputter deposition processes. The passivation layer 128 may serve as a gate dielectric. In some examples, the passivation layer 128 may have a thickness, for instance, of about 5 Angstroms to about 100 Angstroms, such as about 10 Angstroms to about 50 Angstroms.

The gate contact 126 may be a T-shaped gate or a gamma gate, the formation of which is discussed by way of example in U.S. Pat. Nos. 8,049,252, 7,045,404, and 8,120,064, the disclosures of which are incorporated by reference herein. The material of the gate contact 126 may be chosen based on the composition of the first cap layer 116. Materials capable of making a contact (e.g., a Schottky contact) to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

The HEMT device 100 may include additional passivation layer(s) 130 on the semiconductor structure 102, the gate contact 126, and/or other structures of the HEMT device 100. The additional passivation layer(s) 130 may be, for instance, dielectric materials, such as SiO₂, MgOx, MgNx, ZnO, SiNx, SiOx, alloys or layer sequences thereof. The additional passivation layer(s) 130 may be formed using MOCVD process(s), ALD process(s), sputter deposition process(s), or other suitable process(s). One or more insulating layers may be on the HEMT device 100. For instance, as illustrated in FIG. 1, the HEMT device 100 may be encapsulated in an insulating material 132.

A transistor may be formed by the active region between the source contact 122 and the drain contact 124 under the control of a gate contact 126 between the source contact 122 and the drain contact 124. FIG. 1 depicts a cross-sectional view of one unit of an HEMT device 100 for purposes of illustration. The HEMT device 100 may be formed adjacent to additional HEMT device units and may share, for instance, a source contact 122 with adjacent HEMT device units.

In some examples, the HEMT device 100 may be operable at frequencies of up to about 150 GHz. For instance, the HEMT device 100 may be operable at a frequency in a range of about 10 GHz to about 150 GHz, such as in a range of about 30 GHz to about 150 GHz, such as in a range of about 50 GHz to about 150 GHz. In some examples, the HEMT device 100 may have a power density of up to 10 W/mm or greater in these frequency ranges, such as a power density in a range of 2.5 W/mm to about 12 W/mm.

The HEMT device 100 may be electrically coupled to another device, component, or element via electrical connections with the source contact 122 and the drain contact 124. For instance, the HEMT device 100 may be interconnected with one or more additional HEMT devices or other components of a semiconductor package. As illustrated in FIG. 1, the HEMT device may include a first conductive portion 123 electrically coupled to the source contact 122 and a second conductive portion 125 electrically coupled to the drain contact 124. The conductive portions 123, 125 can comprise any suitably electrically conductive material or materials, and extend from the respective source contact 122 and drain contact 124 to any suitable location about the HEMT device 100. Moreover, in some embodiments, the HEMT device 100 may include one or more field plates 134, such as illustrated in FIG. 1. For instance, in some examples, the field plate 134 may be conductively coupled to the gate contact 126. In some examples, at least a portion of the field plate 134 may between the gate contact 126 and the drain contact 124. The field plate 134 may reduce the peak electric field in the HEMT device 100, which may result in increased breakdown voltage and reduced charge trapping. The reduction of the electric field may also yield other benefits such as reduced leakage currents and enhanced reliability. Field plates and techniques for forming field plates are discussed, by way of example, in U.S. Pat. No. 8,120,064, the disclosure of which is incorporated by reference herein.

In some examples, the source contact 122 may be electrically coupled to another device or component using a through-wafer connection, wherein the conductive portion 123 passes through the substrate 104 to the backside of the HEMT device 100. For instance, as illustrated in FIG. 1, the conductive portion 123 may extend away from the source contact 122 through some or all of the insulating material 132. The conductive portion 123 can then laterally traverse away from the source contact 122 before extending back through the insulating material 132, through the semiconductor structure 102, and ultimately through the substrate 104. This configuration can allow the source contact 122 to be electrically coupled to another device or component at the backside of the substrate 104.

In order to facilitate the electrically connection of the conductive portion 123 to the backside of the HEMT device 100, a via can be formed through the semiconductor structure 102 and the substrate 104. The via 200 refers to a channel extending through the one or more layers of the semiconductor structure 102 and substrate 104, such that it can be filled with conductive material and connect with the conductive portion 123 at an intersection 201, such as proximate the boundary between the second cap layer and the additional passivation layer 130. The via 200 will thereby pass through an interface 205 between the semiconductor structure 102 and the substrate 104. As used herein, the interface 205 generally refers to the planar surface between the semiconductor structure 102 and the substrate 104 that is substantially orthogonal to the growth direction 108. In some examples, such as that illustrated in FIG. 1, the via 200 may pass through the semiconductor structure 102 and the substrate 104 along a path that is substantially orthogonal to the interface 205. However, those of ordinary skill in the art, using the disclosures provided herein, will understand that that alternative pathways, angles or configurations of the via 200 may also be realized without deviating from the scope of the present disclosure.

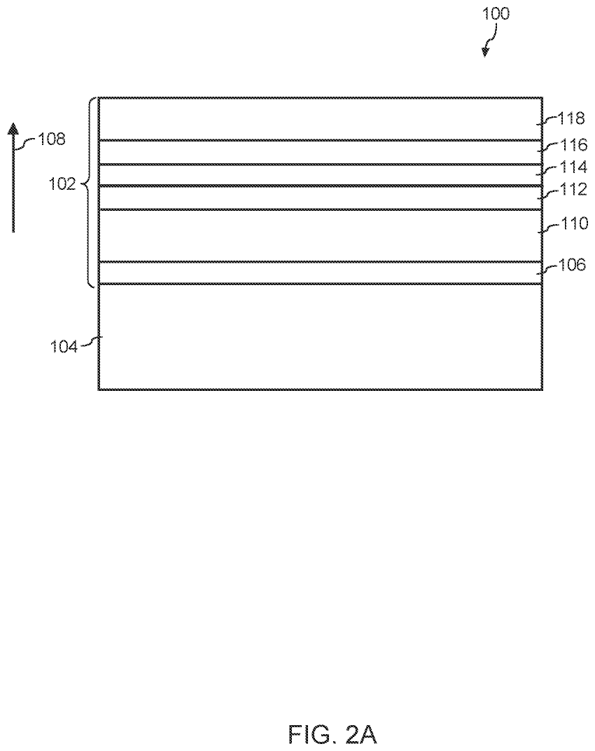

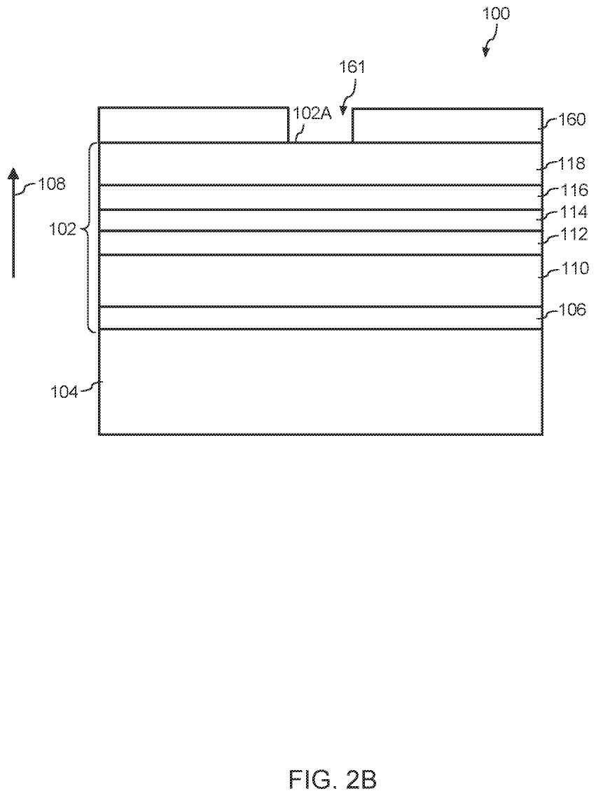

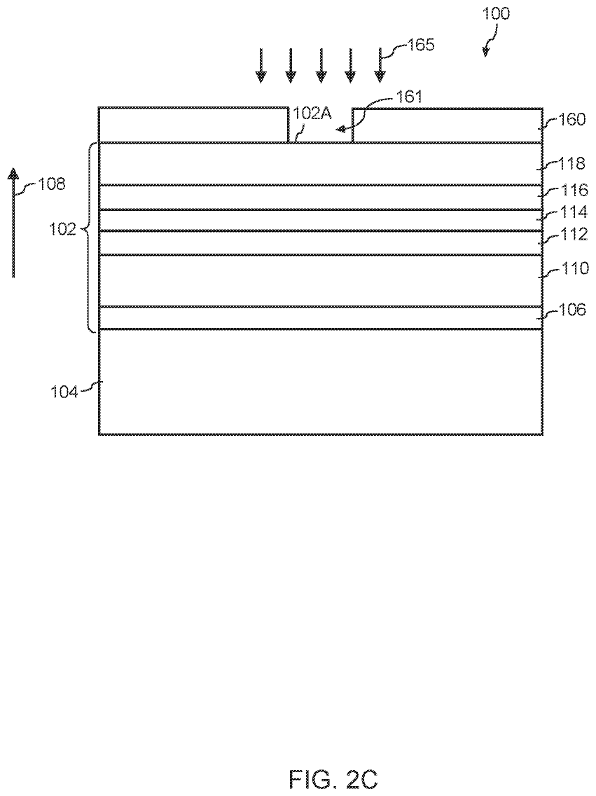

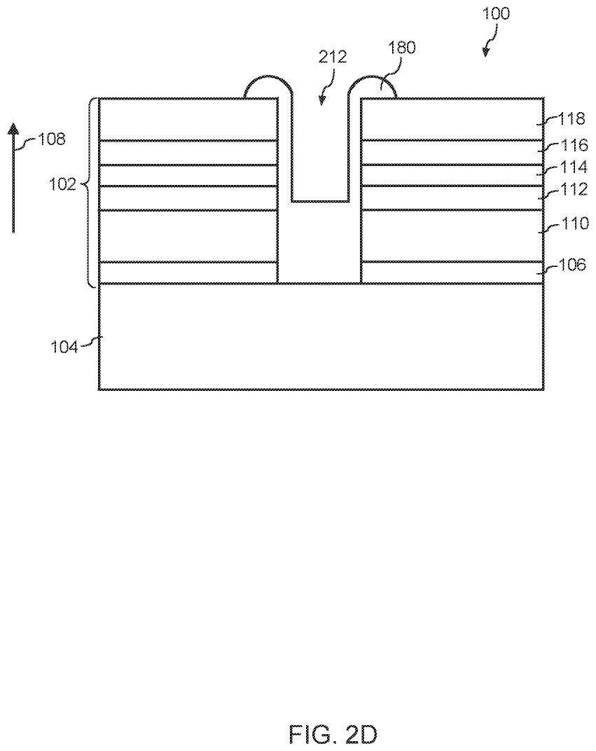

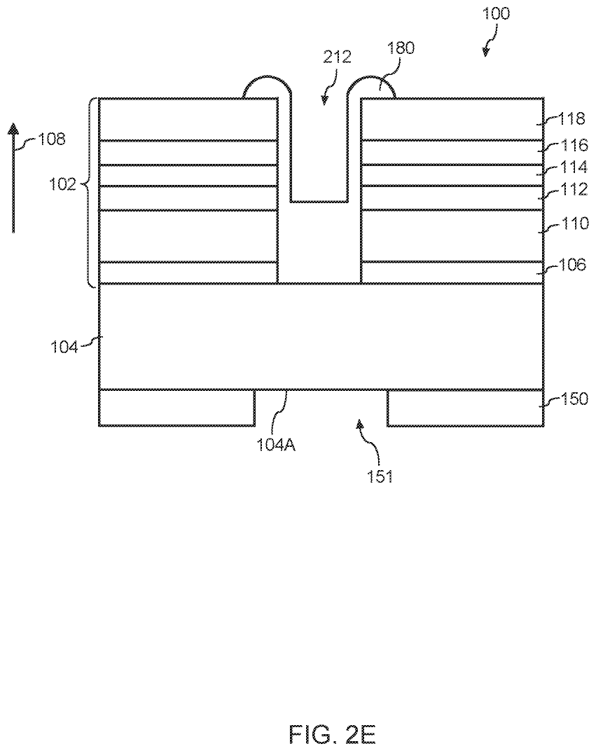

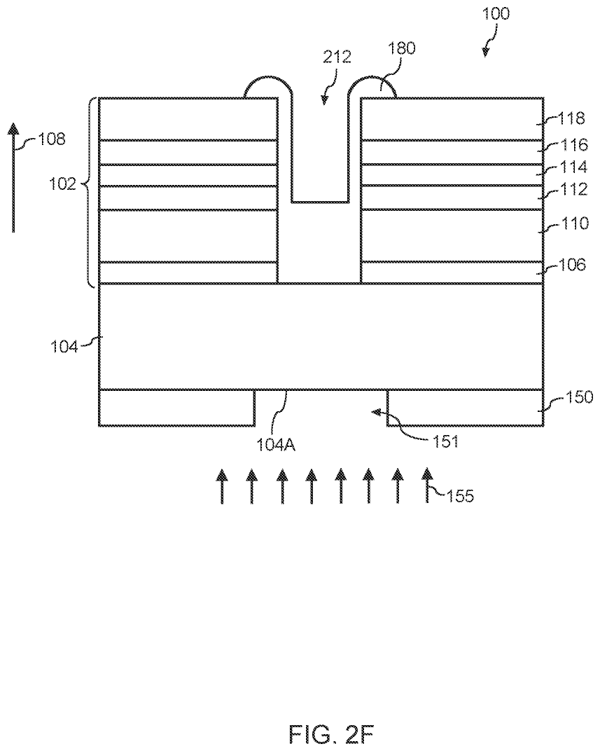

FIGS. 2A-2F are cross-sectional views illustrating aspects of the formation of the via in semiconductor devices, such as the HEMT device 100 of FIG. 1, according to example embodiments of the present disclosure. FIGS. 2A-2F are intended to represent structures for identification and description and are not intended to represent the structures to physical scale. FIGS. 2A-2F depict example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

In FIG. 2A the semiconductor structure 102 is formed on the substrate 104. The semiconductor structure 102 may be an N-polar Group III-nitride semiconductor structure. The semiconductor structure 102 may be epitaxially grown on the substrate 104. The semiconductor structure 102 may include a channel layer 114 that is buried below the top surface of the semiconductor structure 102. The semiconductor structure 102 may be deposited by MOCVD or by other techniques known to those of skill in the art, such as MBE or HVPE.

In the example of FIG. 2A, the semiconductor structure 102 is a multilayer N-polar Group III-nitride semiconductor structure. The semiconductor structure 102 may include, for instance, a first layer 106 (e.g., a nucleation layer), a second layer 110 (e.g., a buffer layer), a barrier layer 112, a channel layer 114, a first cap layer 116, and a second cap layer 118. Details concerning these example layers are described above with reference to FIG. 1.

Referring to FIG. 2B, a first mask 160 is formed on an outer surface 102A of the semiconductor structure 102, such as the outer surface of the second cap layer 118 as illustrated. The first mask 160 may comprise any material suitable for preventing etching of the portion of the semiconductor structure 102 covered by the first mask 160 during subsequent etching operations. For instance, in some examples, the first mask 160 may comprise photoresist. In some examples, the first mask 160 may comprise SiN or SiO₂.

A first window 161 can be present in the first mask 160 to provide selective etch access to a portion of the semiconductor structure 102. In some examples, the first window may be formed through selective placement of the first mask 160 by omitting placement of mask material where etching is desired (e.g., using a photolithography process). In some examples, the first window 161 may be produced by selective removal of mask material where etching is desired.

Referring to FIG. 2C, a first etch 165 is performed on the outer surface 102A of the semiconductor structure 102 with the first mask 160. That is, the first etch 165 is performed to remove material from the semiconductor structure 102 where the first window 161 is present in the first mask 160.

In some embodiments, the first etch 165 can be or can include a dry etch process. For instance, the dry etch process may include a plasma-based dry etch process (e.g., using a pulsed plasma or a continuous plasma). Additionally, or alternative, the dry etch process may include, but not be limited to, gas etching, physical dry etching (e.g., ion, electron, or photon etching), chemical dry etching (e.g., vapor etching), or physical-chemical etching (e.g., reactive ion etching). For instance, in some examples, the dry etch process may include chlorine based gases such as Cl2 or BCl₃.

In some embodiments, the first etch 165 can be or can include a wet etch process. For instance, the wet etch process may include, but not be limited to, using potassium hydroxide, ethylenediamine pyrocatechol, potassium hexacyanoferrate, tetramethylammonium hydroxide, hydrofluoric acid, nitric acid, acetic acid, or combinations thereof.

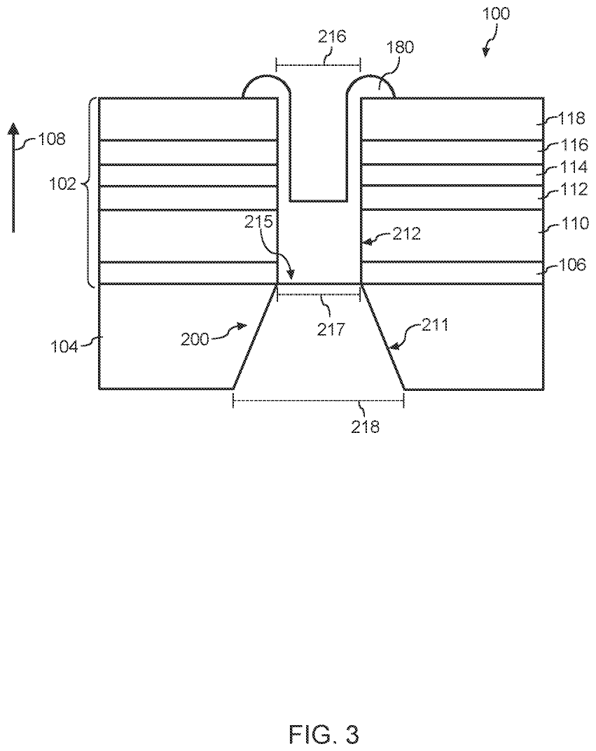

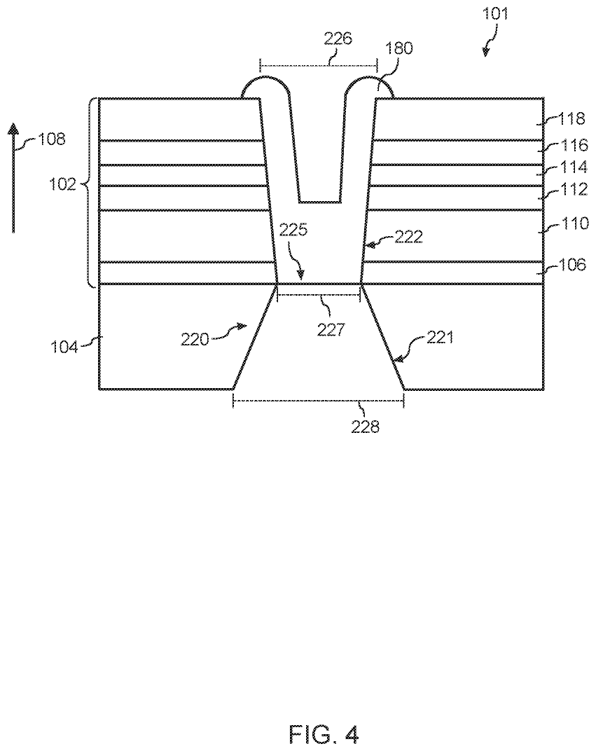

As illustrated in FIG. 2D, a portion 212 of the via is formed in the semiconductor structure 102 by selective removal of the one or more layers via the first etch. The shape and configuration of the portion 212 of the via formed int the semiconductor structure will be discussed with reference to FIGS. 3 and 4 below. In some instances, an etch stop 180 (e.g., a metal etch stop) can be disposed in the semiconductor structure 102. That is, the etch stop 180 can be disposed in the portion 212 of the via 200 in the semiconductor structure 102. For instance, the etch stop 180 can provide a stopping point for subsequent backside etching as disclosed herein. The etch stop 180 can thus, for example, comprise any material suitable to resist etching from the etching process performed on the substrate 104, such as one or more metals.

Referring to FIG. 2E, a second mask 150 is formed on an outer surface 104A of the substrate 104. The second mask 150 may comprise any material suitable for preventing etching of the portion of the substrate covered by the second mask 150 during subsequent etching operations. For instance, the second mask 150 may comprise photoresist, selective organic material such as SU-8, or hard masks such as indium titanium oxide (ITO), Al, Ti, or Ni.

A second window 151 can be present in the second mask 150 to provide selective etch access to a portion of the substrate 104. In some examples, the second window 151 may be formed through selective placement of the second mask 150 by omitting placement of mask material where etching is desired. In some examples, the second window 151 may be produced by selective removal of mask material where etching is desired.

Referring to FIG. 2F, a second etch 155 is performed on the outer surface 104A of the substrate 104 with the second mask 150. That is, the second etch 155 is performed to remove material from the substrate 104 where the second window 151 is present in the second mask 150. In some instances, the portion 212 of the via 200 in the semiconductor structure 102 can include the etch stop 180 that may be resistive to the etch material used in the second etch 155. In such instances, the second etch 155 may etch through the substrate 104 and stop at the etch stop 180. In some instances, this stopping point of the second etch 155 due to the etch stop 180 may be at or proximate the interface between the substrate 104 and the semiconductor structure 102.

In some embodiments, the second etch 155 can be or include a dry etch process. For instance, the dry etch process may include, but not be limited to, using sulfur hexafluoride, oxygen, or fluoroform. In some embodiments, the second etch 155 can be or include a wet etch process. For instance, the wet etch process may include, but not be limited to, using potassium hydroxide, ethylenediamine pyrocatechol, potassium hexacyanoferrate, tetramethylammonium hydroxide, hydrofluoric acid, nitric acid, acetic acid, or combinations thereof. The combined etching operations will thereby provide a single via extending through both the substrate 104 and the semiconductor structure 102, as discussed and illustrated with reference to FIGS. 3 and 4 below.

FIGS. 3 and 4 are cross-sectional views illustrating aspects of the formation of the vias in semiconductor devices, such as the HEMT device 100 of FIG. 1, according to example embodiments of the present disclosure. FIGS. 3 and 4 are intended to represent structures for identification and description and are not intended to represent the structures to physical scale. FIGS. 3 and 4 depict example configurations for purposes of illustration and discussion.

In FIG. 3, a via 200 is present in a portion of the semiconductor device 100, such as the HEMT device of FIG. 1. The via 200 may have been formed using the multiple (e.g., dual) etch process discussed and illustrated with reference to FIGS. 2A-2F. In the example of FIG. 3, the semiconductor structure 102 is a multilayer N-polar Group III-nitride semiconductor structure. The semiconductor structure 102 may include, for instance, a first layer 106 (e.g., a nucleation layer), a second layer 110 (e.g., a buffer layer), a barrier layer 112, a channel layer 114, a first cap layer 116, and a second cap layer 118. Details concerning these example layers are described above with reference to FIG. 1. However, those of ordinary skill in the art, using the disclosures provided herein, will understand the semiconductor structure 102 may include a variety of different structures, such as a variety of different N-polar Group III-nitride semiconductor structures, such as with additional or fewer layers, without deviating from the scope of the present disclosure.

The via 200 passes through the substrate 104 and the semiconductor structure 102. As a result of the multiple (e.g., dual) etching process disclosed herein, the via 200 has a first portion 211 passing through the substrate 104, and a second portion 212 passing through the semiconductor structure 102. The first portion 211 and the second portion 212 of the via 200 meet at the interface 215. In some instances, such as that illustrated in FIG. 3, the interface 215 is between the substrate 104 and the semiconductor structure 102. In some instances, the second portion 212 includes the etch stop 180 that terminates between the first portion 211 and the second portion 212 of the via 200 (e.g., at the interface 215 between the substrate 104 and semiconductor structure 102) as a result of the etching process used on the substrate 104.

Moreover, the first portion 211 and the second portion 212 can have different cross-sectional profiles as a result of the multiple (e.g., two) separate etching processes. For instance, a wet etch process can produce a cross-sectional profile that narrows as the etch penetrates into the material from the outer and unmasked surface. Conversely, a dry etch process can produce a substantially constant cross-sectional profile as the etch penetrates into the material from the outer and unmasked surface. Moreover, even where similar etch processes are used for both the substrate 104 and the semiconductor structure 102 (e.g., two or more wet etch processes), the first portion 211 and second portion 212 of the via 200 may have different cross-sectional profiles due to different etch times, material or chemical interactions, process parameters, or the like. Thus, the cross-sectional profile of the via 200 can change, such as at the interface 215 between the substrate 104 and the semiconductor structure 102.

For instance, as illustrated in FIG. 3, the via 200 includes a cross-sectional profile in the first portion 211 (i.e., in the substrate 104) that narrows as it approaches the interface 215. The narrowing cross-sectional profile may be a result of, for example, a wet etch process performed on the backside of the semiconductor device 100. Conversely, the via 200 includes a cross-sectional profile in the second portion 212 (i.e., in the semiconductor device structure 102) that is substantially constant between the outer surface and the interface 215. The substantially constant cross-sectional profile may be a result of, for example, a dry etch process performed on the frontside of the semiconductor device 100. Thus, the cross-sectional profile of the via 200 changes from narrowing (in the first portion 211) to substantially constant (in the second portion) at the interface 215.

As a result of the different cross-sectional profiles, the via 200 can have different cross-sectional widths at different locations. As used herein, cross-sectional width refers to the width of the via 200 in a directional substantially parallel with the interface 215 between the substrate 104 and the semiconductor structure 102, and thus substantially orthogonal with the growth direction 108. For instance, the via 200 can have a first cross-sectional width 216 on a first side of the semiconductor structure 102 corresponding to its outer surface (i.e., the surface of the semiconductor structure 102 opposite the interface 215 with the substrate 104). Moreover, the via 200 can have a second cross-sectional width 217 at the interface 215. The first cross-sectional width 216 may be greater than or equal to the second cross-sectional width 217. For instance, as illustrated in FIG. 3, the first cross-sectional width 216 may be substantially the same as the second cross-sectional width 217, such as a result of a dry etch through the semiconductor structure 102 towards the interface 215 with the substrate 104.

Likewise, the via 200 can have a third cross-sectional width 218 on a first side of the substrate 104 corresponding to its outer surface (i.e., the surface of the substrate 104 opposite the interface 215 with the semiconductor structure 102). The third cross-sectional width 218 can be greater than or equal to the second cross-sectional width 217. For instance, as illustrated in FIG. 3, the third cross-sectional width 218 may be greater than the second cross-sectional width 217, such as a result of a wet etch through the substrate 104 towards the interface 215 with the semiconductor structure 102. Depending on the respective etch processes, the first cross-sectional width 216 can be greater than, less than, or substantially the same as the third cross-sectional width 218. For instance, the first cross-sectional width 216 can be less than the third cross-sectional width 218 as illustrated in FIG. 3.

In FIG. 4, another via 220 is present in another semiconductor device 101, such as similar to the HEMT device of FIG. 1 but with a differently configured via. The via 200 may have been formed using the multiple (e.g., dual) etch process discussed and illustrated with reference to FIGS. 2A-2F. Similar to the example of FIG. 3, the semiconductor structure 102 in FIG. 4 is a multilayer N-polar Group III-nitride semiconductor structure. The semiconductor structure 102 may include, for instance, a first layer 106 (e.g., a nucleation layer), a second layer 110 (e.g., a buffer layer), a barrier layer 112, a channel layer 114, a first cap layer 116, and a second cap layer 118. Details concerning these example layers are described above with reference to FIG. 1. However, those of ordinary skill in the art, using the disclosures provided herein, will understand the semiconductor structure 102 may include a variety of different structures, such as a variety of different N-polar Group III-nitride semiconductor structures, such as with additional or fewer layers, without deviating from the scope of the present disclosure.

The via 220 passes through the substrate 104 and the semiconductor structure 102. As a result of the multiple (e.g., dual) etching process disclosed herein, the via 220 has a first portion 221 passing through the substrate 104, and a second portion 222 passing through the semiconductor structure 102. The first portion 221 and the second portion 222 of the via 220 meet at the interface 225. In some instances, such as that illustrated in FIG. 4, the interface 225 is between the substrate 104 and the semiconductor structure 102. In some instances, the second portion 222 includes the etch stop 180 that terminates between the first portion 221 and the second portion 222 of the via 220 (e.g., at the interface 225 between the substrate 104 and semiconductor structure 102) as a result of the etching process used on the substrate 104.

Moreover, as illustrated in FIG. 4, the first portion 221 and the second portion 222 have different cross-sectional profiles as a result of the multiple (e.g., two) etching processes, such as multiple separate wet etch processes. That is, the via 220 includes a cross-sectional profile in the first portion 221 (i.e., in the substrate 104) that narrows as it approaches the interface 215. The narrowing cross-sectional profile may be a result of, for example, a wet etch process performed on the backside of the semiconductor device 101. Similarly, the via 220 includes a cross-sectional profile in the second portion 222 (i.e., in the semiconductor device structure 102) that also narrows as it approaches the interface 215. The second narrowing cross-sectional profile may similarly be a result of, for example, a second wet etch process performed on the frontside of the semiconductor device 101. As a result of the two opposing narrowing cross-sectional profiles, the overall via 220 can collectively comprise an hourglass-shaped cross-sectional profile. A narrow convergence of the hourglass-shaped cross-sectional profile can be located at the interface 215 where the first portion 221 and second portion 222 converge.

As a result of the different cross-sectional profiles, the via 220 has a first cross-sectional width 226 on a first side of the semiconductor structure 102 corresponding to its outer surface (i.e., the surface of the semiconductor structure 102 opposite the interface 215 with the substrate 104). Moreover, the via 220 has a second cross-sectional width 227 at the interface 215. As illustrated in FIG. 4, the first cross-sectional width 226 is greater than the second cross-sectional width 227, such as a result of a wet etch through the semiconductor structure 102 towards the interface 215 with the substrate 104.

Likewise, the via 220 has a third cross-sectional width 228 on a first side of the substrate 104 corresponding to its outer surface (i.e., the surface of the substrate 104 opposite the interface 215 with the semiconductor structure 102). The third cross-sectional width 228 is also greater than the second cross-sectional width 227, such as a result of another wet etch through the substrate 104 towards the interface 215 with the semiconductor structure 102. Depending on the respective etch processes, the first cross-sectional width 226 can be greater than, less than, or substantially the same as the third cross-sectional width 228. For instance, the first cross-sectional width 226 can be less than the third cross-sectional width 228 as illustrated in FIG. 4.

FIGS. 1-4 illustrate semiconductor devices having vias that comprise two portions having different cross-sectional profiles, such as a result of two etch processes. However, without deviating from the scope of the present disclosure, semiconductor devices may include vias having any number of plurality of portions (e.g., more than two), from any number of multiple etch processes, some or all of which have different cross-sectional profiles. For instance, vias may include three portions from three etch processes, with at least two portions having different cross-sectional profiles from one another. In some instances, the vias may include three or more portions, all of which have their own unique respective cross-sectional profile.

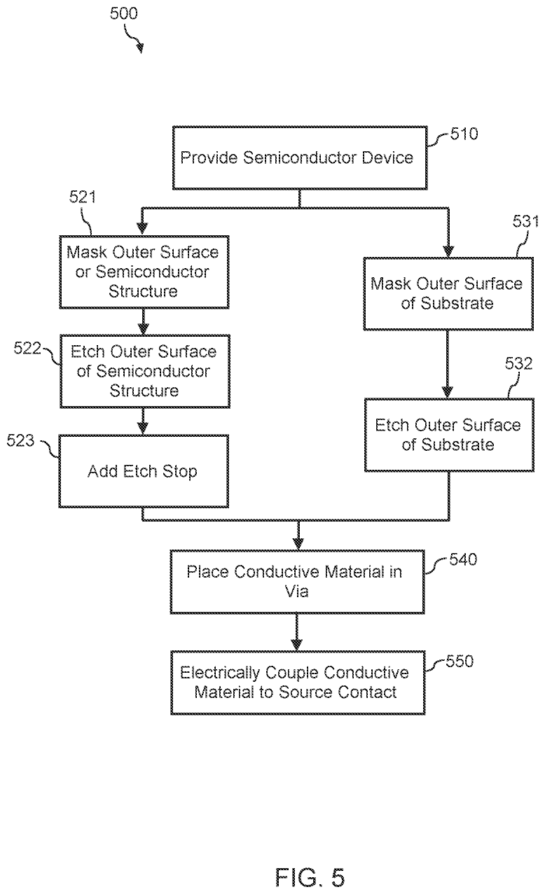

FIG. 5 depicts a flow chart of an example method 500 for forming a semiconductor device according to example embodiments of the present disclosure. FIG. 5 depicts example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 510, the method 500 may include providing a semiconductor device. The semiconductor device may be, for instance, the semiconductor device 100 (e.g., HEMT device 100) described with reference to FIG. 1. For instance, the semiconductor device may comprise an N-polar Group III-nitride semiconductor structure on a substrate, such as a silicon carbide substrate.

At 521 a first mask can be applied to the outer surface of the semiconductor structure. The first mask can include one or more windows that leave a selective portion or portions of the outer surface of the semiconductor structure exposed.

At 522, a first etch can be performed on the outer surface of the semiconductor structure. The first etch can produce a first portion of a via passing through the semiconductor structure to the interface with the substrate. In some examples, the first etch of the semiconductor structure is a wet etch. In some examples, the first etch of the semiconductor structure is a dry etch. In some examples, the first portion of the via created by the first etch has a first cross-sectional width at the outer surface that is greater than or substantially the same as a second cross-sectional profile at the interface between the semiconductor structure and the substrate. In some examples, the first portion of the via created by the first etch has a cross-sectional profile that narrows as it approaches the interface between the semiconductor structure and the substrate. In some examples, the first portion of the via created by the first etch has a substantially constant cross-sectional width between the semiconductor structure and the substrate.

At 523, an etch stop may optionally be added into the semiconductor structure. That is, the etch stop may be added into the via formed from the first etch at 522. The etch stop provides a stopping point for subsequent etching of the substrate as disclosed herein. The etch stop can thus, for example, comprise any material suitable to resist etching from the etching process performed on the substrate, such as one or more metals to define a metal etch stop.

At 531 a second mask can be applied to the outer surface of the substrate. The second mask can include one or more windows that leave a selective portion or portions of the outer surface of the substrate exposed.

At 532, a second etch can be performed on the outer surface of the substrate. The second etch can produce a second portion of a via passing through the substrate to the interface with the semiconductor structure. In some examples, where the etch stop was added in step 523, the second etch at 532 will etch through the substrate until it reaches said etch stop. In some examples, the second etch of the substrate is a wet etch. In some examples, the second portion of the via created by the second etch has a third cross-sectional width at the outer surface that is greater than the second cross-sectional profile at the interface between the semiconductor structure and the substrate. In some examples, the second portion of the via created by the first etch has a cross-sectional profile that narrows as it approaches the interface between the semiconductor structure and the substrate. In some examples, the overall via resulting from both etches has an hourglass-shaped cross-sectional profile with a narrow convergence at the interface.

The masking and etching of the semiconductor structure and substrate can occur in any suitable order. For instance, in some examples, the semiconductor structure mask at 521 and the semiconductor etch at 522 can occur before the substrate mask at 531 and substrate etch at 532. In some examples, the substrate mask at 531 and substrate etch at 532 can occur before the structure mask at 521 and the semiconductor etch at 522. In some examples, all or part of the structure mask at 521 and the semiconductor etch at 522 can occur at the same time, or at a partially overlapping time, as the substrate mask at 531 and substrate etch at 532.

Moreover, while FIG. 5 illustrates the semiconductor structure mask at 521, the semiconductor etch at 522, the substrate mask at 531, and the substrate etch at 532, any number of additional mask and etch steps may further be included in the method 500 without deviating from the scope of the present disclosure. For instance, method 500 may include a third etch step, with or without a third mask step, that can produce a third portion of the via, potentially having a third cross-sectional profile different than the cross-sectional profiles produced from the first two etch steps.

At 540 a conductive portion can be deposited in the via. At 550, the conductive portion can be coupled to the source contact of the semiconductor structure. The deposition of the conductive portion and the electrical coupling of the via to the semiconductor structure can occur as a single step, or as two discrete steps. Moreover, the deposition of the conductive portion and the electrical coupling of the via to the semiconductor structure can be achieved through any suitable process or processes.

Example aspects of the present disclosure are provided in the following paragraphs, the example of which may be combined to form various different embodiments of the present disclosure.

One example aspect of the present disclosure is directed to a semiconductor device. The semiconductor device includes a substrate. The semiconductor device includes a nitrogen-polar (N-polar) Group III-nitride semiconductor structure on the substrate. The semiconductor device includes a via passing through the substrate and the N-polar Group III-nitride semiconductor structure. A cross-sectional profile of the via changes at an interface between the substrate and the N-polar Group III-nitride semiconductor structure.

In some examples, the via has a first cross-sectional profile in the N-polar Group III-nitride semiconductor structure that is substantially constant.

In some examples, the via has a first cross-sectional profile in the N-polar Group III-nitride semiconductor structure that narrows as it approaches the interface.

In some examples, the via has a second cross-sectional profile in the substrate that narrows as it approaches the interface.

In some examples, the cross-sectional profile of the via has an hourglass-shaped cross-sectional profile, and has a narrow convergence of the hourglass-shaped cross-sectional profile at the interface.

In some examples, the N-polar Group III-nitride semiconductor structure includes an N-face at a surface opposite the substrate.

In some examples, the semiconductor device includes an electrode coupled to the N-polar Group III-nitride semiconductor structure.

In some examples, the via has a conductive portion that is electrically coupled to the electrode.

In some examples, the substrate includes a silicon carbide substrate.

In some examples, the semiconductor device is a high electron mobility transistor (HEMT) device.

One example aspect of the present disclosure is directed to a transistor device. The transistor device includes a substrate having a first side and an opposing second side. The transistor device includes a nitrogen-polar (N-polar) Group III-nitride semiconductor structure having a first side and an opposing second side. The first side of the N-polar Group III-nitride semiconductor structure is on the second side of the substrate to define an interface. The transistor device includes a via passing through the substrate and the N-polar Group III-nitride semiconductor structure. The via has a first cross-sectional width at the second side of the N-polar Group III-nitride semiconductor structure and a second cross-sectional width at the interface. The first cross-sectional width is greater than or equal to the second cross-sectional width.

In some examples, the first cross-sectional width is greater than the second cross-sectional width.

In some examples, the first cross-sectional width is substantially the same as the second cross-sectional width.

In some examples, the via has a third cross-sectional width at the first side of the substrate, and wherein the third cross-sectional width is greater than or equal to the second cross-sectional width.

In some examples, the N-polar Group III-nitride semiconductor structure includes a barrier layer, wherein the barrier layer comprises N-polar Al_{w}Ga_{1-w}N, where 0.1≤w≤0.4. The N-polar Group III-nitride semiconductor structure includes a channel layer on the barrier layer, wherein the channel layer comprises N-polar AlₓGa₁₋ₓN, where 0≤x≤0.1.

In some examples, the N-polar Group III-nitride semiconductor structure includes a buffer layer. The barrier layer is on the buffer layer such that the barrier layer is between the buffer layer and the channel layer.

In some examples, the buffer layer includes N-polar AlᵥGa₁₋ᵥN, where 0≤v≤0.1.

In some examples, the transistor device includes one or more cap layers on the channel layer.

In some examples, the transistor device includes a gate contact, a source contact, and a drain contact on the N-polar Group III-nitride semiconductor structure.

In some examples, the gate contact is between the source contact and the drain contact.

In some examples, the via comprises a conductive portion that is electrically coupled to the source contact.

In some examples, the transistor device includes an electrode coupled to the N-polar Group III-nitride semiconductor structure.

In some examples, the via has a conductive portion that is electrically coupled to the electrode.

In some examples, the substrate includes a silicon carbide substrate.

In some examples, the transistor device is a high electron mobility transistor (HEMT) device.

One example aspect of the present disclosure is directed to a method for forming a semiconductor device. The semiconductor device includes a nitrogen-polar (N-polar) Group III-nitride semiconductor structure on a substrate. The method includes performing a first etch on an outer surface of the N-polar Group III-nitride semiconductor structure. The method includes performing a second etch on an outer surface of the substrate. The first etch and the second etch combine to produce a via passing through the substrate and the N-polar Group III-nitride semiconductor structure.

In some examples, a cross-sectional profile of the via changes at an interface between the substrate and the N-polar Group III-nitride semiconductor structure.

In some examples, a first portion of the via has a first cross-sectional profile that is substantially constant between the outer surface of the N-polar Group III-nitride semiconductor structure and an interface between the substrate and the N-polar Group III-nitride semiconductor structure.

In some examples, a second portion of the via has a second cross-sectional profile in the substrate that narrows as it approaches the interface.

In some examples, a first portion of the via has a first cross-sectional profile in the N-polar Group III-nitride semiconductor structure that narrows as it approaches an interface between the substrate and the N-polar Group III-nitride semiconductor structure.

In some examples, the first etch includes a dry etch process.

In some examples, the second etch includes a wet etch process.

In some examples, the first etch includes a wet etch process.

In some examples, the N-polar Group III-nitride semiconductor structure includes a barrier layer, wherein the barrier layer comprises N-polar Al_{w}Ga_{1-w}N, where 0.1≤w≤0.4. The semiconductor structure includes a channel layer on the barrier layer, wherein the channel layer comprises N-polar AlₓGa₁₋ₓN, where 0≤x≤0.1.

In some examples, the N-polar Group III-nitride semiconductor structure includes a buffer layer. The barrier layer is on the buffer layer such that the barrier layer is between the buffer layer and the channel layer.

In some examples, the buffer layer comprises N-polar AlᵥGa₁₋ᵥN, where 0≤v≤0.1.

In some examples, the method includes depositing a conductive portion in the via.

In some examples, the method includes electrically coupling the conductive portion to an electrode coupled to the N-polar Group III-nitride semiconductor structure.

In some examples, the method includes disposing an etch stop in the N-polar Group III-nitride semiconductor structure between performing the first etch and the second etch

In some examples, the substrate comprises a silicon carbide substrate.

In some examples, the semiconductor device is a high electron mobility transistor device.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a substrate;
a nitrogen-polar (N-polar) Group III-nitride semiconductor structure on the substrate; and
a via passing through the substrate and the N-polar Group III-nitride semiconductor structure, wherein a cross-sectional profile of the via changes at an interface between the substrate and the N-polar Group III-nitride semiconductor structure.

2. The semiconductor device of claim 1, wherein the via has a first cross-sectional profile in the N-polar Group III-nitride semiconductor structure that is substantially constant.

3. The semiconductor device of claim 1, wherein the via has a first cross-sectional profile in the N-polar Group III-nitride semiconductor structure that narrows as it approaches the interface.

4. The semiconductor device of claim 3, wherein the via has a second cross-sectional profile in the substrate that narrows as it approaches the interface.

5. The semiconductor device of claim 1, wherein the cross-sectional profile of the via comprises an hourglass-shaped cross-sectional profile, and wherein a narrow convergence of the hourglass-shaped cross-sectional profile is at the interface.

6. The semiconductor device of claim 1, wherein the N-polar Group III-nitride semiconductor structure comprises an N-face at a surface opposite the substrate.

7-8. (canceled)

9. The semiconductor device of claim 1, wherein the substrate comprises a silicon carbide substrate.

10. The semiconductor device of claim 1, wherein the semiconductor device is a high electron mobility transistor (HEMT) device.

11. A transistor device, comprising:
a substrate having a first side and an opposing second side;
a nitrogen-polar (N-polar) Group III-nitride semiconductor structure having a first side and an opposing second side, the first side of the N-polar Group III-nitride semiconductor structure being on the second side of the substrate to define an interface; and
a via passing through the substrate and the N-polar Group III-nitride semiconductor structure,
wherein the via has a first cross-sectional width at the second side of the N-polar Group III-nitride semiconductor structure and a second cross-sectional width at the interface, and wherein the first cross-sectional width is greater than or equal to the second cross-sectional width.

12. The transistor device of claim 11, wherein the first cross-sectional width is greater than the second cross-sectional width.

13. The transistor device of claim 11, wherein the first cross-sectional width is substantially the same as the second cross-sectional width.

14. The transistor device of claim 11, wherein the via has a third cross-sectional width at the first side of the substrate, and wherein the third cross-sectional width is greater than or equal to the second cross-sectional width.

15. The transistor device of claim 11, wherein the N-polar Group III-nitride semiconductor structure comprises:
a barrier layer, wherein the barrier layer comprises N-polar Al_{w}Ga_{1-w}N, where 0.1≤w≤0.4; and
a channel layer on the barrier layer, wherein the channel layer comprises N-polar AlₓGa₁₋ₓN, where 0≤x≤0.1.

16. The transistor device of claim 15, wherein the N-polar Group III-nitride semiconductor structure comprises a buffer layer, wherein the barrier layer is on the buffer layer such that the barrier layer is between the buffer layer and the channel layer.

17. The transistor device of claim 16, wherein the buffer layer comprises N-polar AlᵥGa₁₋ᵥN, where 0≤v≤0.1.

18. The transistor device of claim 15, further comprising one or more cap layers on the channel layer.

19-25. (canceled)

26. A method for forming a semiconductor device comprising a nitrogen-polar (N-polar) Group III-nitride semiconductor structure on a substrate, the method comprising:
performing a first etch on an outer surface of the N-polar Group III-nitride semiconductor structure; and
performing a second etch on an outer surface of the substrate,
wherein the first etch and the second etch combine to produce a via passing through the substrate and the N-polar Group III-nitride semiconductor structure.

27. The method of claim 26, wherein a cross-sectional profile of the via changes at an interface between the substrate and the N-polar Group III-nitride semiconductor structure.

28. The method of claim 26, wherein a first portion of the via has a first cross-sectional profile that is substantially constant between the outer surface of the N-polar Group III-nitride semiconductor structure and an interface between the substrate and the N-polar Group III-nitride semiconductor structure.

29. The method of claim 28, wherein a second portion of the via has a second cross-sectional profile in the substrate that narrows as it approaches the interface.

30-41. (canceled)
